(19) United States
(12) Patent Application Publication
(10) Pub. No.: US 2025/0160133 A1
(43) Pub. Date: May 15, 2025

(54) DISPLAY DEVICE

(71) Applicant: LG Display Co., Ltd., Seoul (KR)

(72) Inventor: EunYoung PARK, Paju-si (KR)

(73) Assignee: LG Display Co., Ltd., Seoul (KR)

(21) Appl. No.: 18/894,677

(22) Filed: Sep. 24, 2024

(30) Foreign Application Priority Data
Nov. 10, 2023 (KR) 10-2023-0154990

(51) Int. Cl. H10K 59/122; H10K 59/80; H10K 102/00

(52) U.S. Cl. CPC H10K 59/122; H10K 59/80515; H10K 59/874; H10K 2102/331

(57) ABSTRACT

Embodiments of the disclosure relate to a display device and an organic light emitting element and, more specifically, may enhance the reliability of the display device and the organic light emitting element by including an anode electrode disposed on a substrate, a bank layer disposed on a portion on the anode electrode, a getter layer disposed in at least a partial area of the bank layer, a light emitting layer disposed on the getter layer and the anode electrode, and a cathode electrode disposed on the light emitting layer.

### CROSS-REFERENCE TO RELATED APPLICATION

This application claims priority from Korean Patent Application No. 10-2023-0154990, filed on Nov. 10, 2023, which is hereby incorporated by reference for all purposes as if fully set forth herein.

### BACKGROUND

### Technical Field

Embodiments of the disclosure relate to a display device.

### Discussion of the Related Art

The advent of the information age leads to a fast advance in the field of displays which visually display electrical information signals, and steady research efforts to develop compact and lightweight, low-power displays while enhancing the performance of displays.

Among display devices, light emitting display devices, as self-luminous, do not require a separate light source, unlike liquid crystal displays, and may be manufactured in a slim and lightweight form.

However, lighter and thinner light emitting display device are vulnerable to contaminants generated inside and outside the device, causing deterioration of performance and reliability.

Further, as much of the light emitted from the light emitting display device is trapped inside rather than exiting the light emitting display device, the light extraction efficiency of the light emitting display device may deteriorate.

### SUMMARY

Accordingly, embodiments of the present disclosure are directed to a display device that substantially obviates one or more of the problems due to limitations and disadvantages of the related art.

An aspect of the disclosure is to provide a display device with enhanced reliability.

Another aspect of the disclosure is to provide a display device with enhanced light extraction efficiency.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise an anode electrode disposed on a substrate, a bank layer disposed on a portion of the anode electrode, a getter layer disposed in at least a partial area of the bank layer, a light emitting layer disposed on the getter layer and the anode electrode, and a cathode electrode disposed on the light emitting layer. The getter layer is a layer including a plurality of nanoparticles. The plurality of nanoparticles may be disposed to be spaced apart from each other on the bank layer.

In another aspect, a display device may comprise a first planarization layer on a substrate, a second planarization layer disposed on the first planarization layer and including an opening, a bank layer disposed on the second planarization layer, and a getter layer disposed in at least a partial area on the bank layer. The getter layer is a layer including a plurality of nanoparticles. The plurality of nanoparticles may be disposed to be spaced apart from each other on the bank layer.

According to embodiments of the disclosure, there may be provided a display device with enhanced reliability.

According to embodiments of the disclosure, there may be provided a display device with enhanced light extraction efficiency.

According to embodiments of the disclosure, there may be provided a display device capable of low-power consumption by enhancing light extraction efficiency.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a view illustrating an example of a structure of a display device and a circuit structure included in a subpixel according to embodiments of the disclosure.

FIG. 2 is a view illustrating an example of a cross-sectional structure of a conventional display device.

FIG. 3 is a view illustrating an example of a cross-sectional structure of a display device according to embodiments of the disclosure.

FIG. 4 is an enlarged view of area A of FIG. 3.

FIG. 5 is a view illustrating various examples of part B of FIG. 4.

FIG. 6 is a graph illustrating changes in characteristics of a display device according to embodiments of the disclosure.

FIGS. 7A and 7B are views illustrating another example of a cross-sectional structure of a display device according to embodiments of the disclosure.

FIGS. 8A, 8B, 8C, 8D, 8E, and 8F are views illustrating an example of a method for manufacturing a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

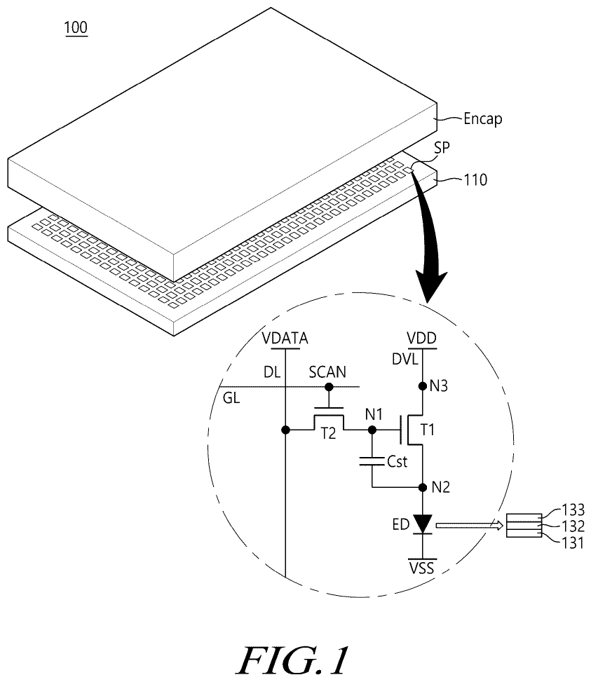

FIG. 1 is a view illustrating an example of a structure of a display device and a circuit structure included in a subpixel according to embodiments of the disclosure.

Referring to FIG. 1, a plurality of subpixels SP may be disposed in a display area of the display device 100.

Each of the plurality of subpixels SP may include a light emitting element ED and a subpixel circuit unit configured to drive the light emitting element ED.

The subpixel circuit unit may include a driving transistor T1 for driving the light emitting element ED, a scan transistor T2 for transferring the data voltage VDATA to the first node N1 of the driving transistor T1, and a storage capacitor Cst for maintaining a constant voltage during one frame.

The driving transistor T1 may include the first node N1 to which the data voltage may be applied, a second node N2 electrically connected with the light emitting element ED, and a third node N3 to which a driving voltage VDD is applied from a driving voltage line DVL. The first node N1 in the driving transistor T1 may be a gate node, the second node N2 may be a source node or a drain node, and the third node N3 may be the drain node or the source node. For convenience of description, described below is an example in which the first node N1 in the driving transistor T1 is a gate node, the second node N2 is a source node, and the third node N3 is a drain node.

The light emitting element ED may include an anode electrode 131, a light emitting layer 132, and a cathode electrode 133. The anode electrode 131 may be a pixel electrode disposed in each subpixel SP and be electrically connected to the second node N2 of the driving transistor T1 of each subpixel SP. The cathode electrode 133 may be a common electrode commonly disposed in the plurality of subpixels SP, and a base voltage VSS may be applied thereto.

Conversely, the anode electrode 131 may be a common electrode, and the cathode electrode 133 may be a pixel electrode. Hereinafter, for convenience of description, it is assumed that the anode electrode 131 is a pixel electrode and the cathode electrode 133 is a common electrode.

The light emitting element ED may have one or more predetermined emission areas.

The light emitting element ED may be an organic light emitting diode (OLED), an inorganic light emitting diode, or a quantum dot light emitting element. When the light emitting element ED is an organic light emitting diode, the light emitting layer 132 of the light emitting element ED may include an organic light emitting layer 132 including an organic material.

The scan transistor T2 may be on/off controlled by a scan signal SCAN, which is a gate signal, applied via the gate line GL and be electrically connected between the first node N1 of the driving transistor T1 and the data line DL.

The storage capacitor Cst may be electrically connected between the first node N1 and second node N2 of the driving transistor T1.

The subpixel circuit unit may have a 2T (transistor) 1C (capacitor) structure which includes two transistors DT and ST and one capacitor Cst and, in some cases, each subpixel SP may further include one or more transistors or one or more capacitors.

The capacitor Cst may be an external capacitor intentionally designed to be outside the driving transistor T1, but not a parasite capacitor (e.g., Cgs or Cgd) which is an internal capacitor that may be present between the first node N1 and the second node N2 of the driving transistor T1. Each of the driving transistor T1 and the scan transistor T2 may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer Encap may be disposed on the display panel 110 to prevent penetration of external moisture or oxygen into the circuit elements (particularly, the light emitting element ED). The encapsulation layer Encap may be disposed to cover the light emitting elements ED.

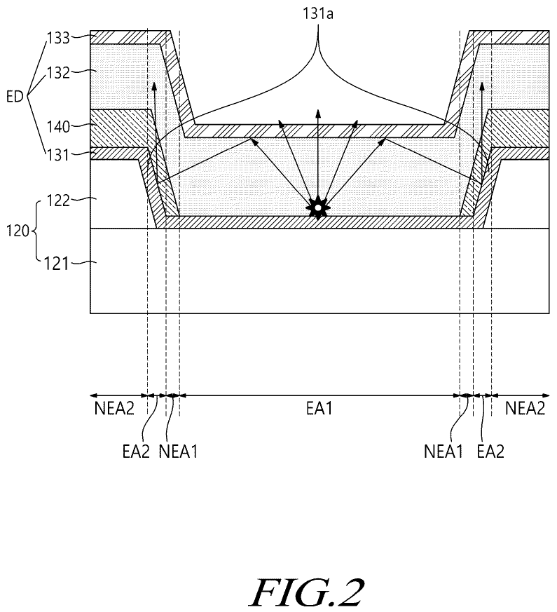

FIG. 2 is a view illustrating an example of a cross-sectional structure of a conventional display device.

Referring to FIG. 2, a display panel 110 of a display device 100 may include a substrate (not shown) on which a plurality of subpixels SP including a plurality of emission areas and a plurality of non-emission areas are disposed.

The plurality of emission areas may include a first emission area EA1 and a second emission area EA2. The first emission area EA1 may be defined as an area where the anode electrode 131, the light emitting layer 132, and the cathode electrode 133 overlap. The second emission area EA2 may be defined as an area where the anode electrode 131 has an anode electrode inclined portion 131a, as is described below.

The plurality of non-emission areas may include a first non-emission area NEA1 and a second non-emission area NEA2. The first non-emission area NEA1 may refer to an area between the first emission area EA1 and the second emission area EA2. The second non-emission area NEA2 may refer to an area outside the second emission area EA2.

A planarization layer 120 may be disposed on the substrate.

The planarization layer 120 may include a first planarization layer 121 and a second planarization layer 122 disposed on the first planarization layer 121.

The planarization layer 120 may protect the thin film transistor disposed below and may alleviate or planarize a step due to various patterns.

The planarization layer 120 may be formed of at least one of organic insulating materials such as, but not limited to, benzocyclobutene (BCB), an acryl resin, an epoxy resin, a phenolic resin, a polyamide resin, or a polyimide resin.

The first planarization layer 121 and the second planarization layer 122 may be formed of the same material, but is not limited thereto.

The second planarization layer 122 may include at least one opening. The opening of the second planarization layer 122 may be positioned in a portion of the first emission area EA1, the first non-emission area NEA1, and the second emission area EA2. The second planarization layer 122 may be positioned in a portion of the second emission area EA2 and the second non-emission area NEA2.

An anode electrode 131 may be disposed on the first planarization layer 121 and the second planarization layer 122.

When the display device 100 is a top emission type, the anode electrode 131 is a reflective electrode that reflects light and may be disposed using an opaque conductive material.

As the second planarization layer 122 has an opening, the anode electrode 131 may be disposed to have a concave shape.

As the anode electrode 131 is disposed to have a concave shape, the anode electrode 131 may have an anode electrode inclined portion 131a in the second emission area EA2.

The thickness of the anode electrode inclined portion 131a may be thinner than the thickness of another portion of the anode electrode 131.

When the anode electrode 131 is a reflective electrode, a portion of the light emitted from the first emission area EA1 may be reflected from the anode electrode inclined portion 131a and travel upward as illustrated in FIG. 2.

The second emission area EA2 may be defined as an area in which light emitted from the first emission area EA1 is reflected and emitted, or may be defined as an area in which the anode electrode inclined portion 131a is disposed.

A bank layer 140 may be disposed on the anode electrode 131 and the second planarization layer 122.

The bank layer 140 may be formed of at least one of an inorganic insulating material such as silicon nitride (SiNx) or silicon oxide (SiOx) or an organic insulating material such as benzocyclobutene (BCB), acryl resin, epoxy resin, phenolic resin, polyamide resin, or polyimide resin, but is not limited thereto.

The bank layer 140 may have an opening area, and the first emission area EA1 may be defined by the opening area of the bank layer 140. In other words, the bank layer 140 may be disposed in an area other than the first emission area EA1.

The light emitting layer 132 may be disposed on the bank layer 140. The light emitting layer 132 may further include, in addition to the organic light emitting layer, a hole injection layer, a hole transport layer, an electron transport layer, and an electron transport layer, but is not limited thereto.

The light emitting layer 132 may be formed only in the first emission area EA1 or may be formed in both the second emission area EA2 and the first and second non-emission areas NEA1 and NEA2 as illustrated in FIG. 2, but is not limited thereto.

The cathode electrode 133 may be disposed on the light emitting layer 132.

When the display device 100 is a top emission type, the cathode electrode 133 may be disposed using a transparent conductive material that transmits light.

An encapsulation layer Encap (not shown) may be disposed on the cathode electrode CE.

The encapsulation layer Encap may include a first encapsulation layer, a second encapsulation layer disposed on the first encapsulation layer, and a third encapsulation layer disposed on the second encapsulation layer.

The encapsulation layer Encap may be formed of a transparent material to transmit light emitted from the light emitting layer 132.

As described above with reference to FIG. 2, the conventional display device 100 may have a second emission area EA2 formed as the anode electrode inclined portion 131a is disposed in addition to the first emission area EA1, thereby increasing light extraction efficiency. However, there is a first non-emission area NEA1 between the first emission area EA1 and the second emission area EA2, and the size of the second emission area EA2 is smaller than the size of the first emission area EA1, so there is a limitation in increasing the light extraction efficiency by a predetermined level or more.

Further, as the display device 100 becomes smaller and thinner, the display device 100 becomes more vulnerable to harmful gases generated inside and outside, and a faulty dark spot may easily occur, so that the performance of the display device 100 may be easily deteriorated, and accordingly, the reliability of the display device 100 may be reduced.

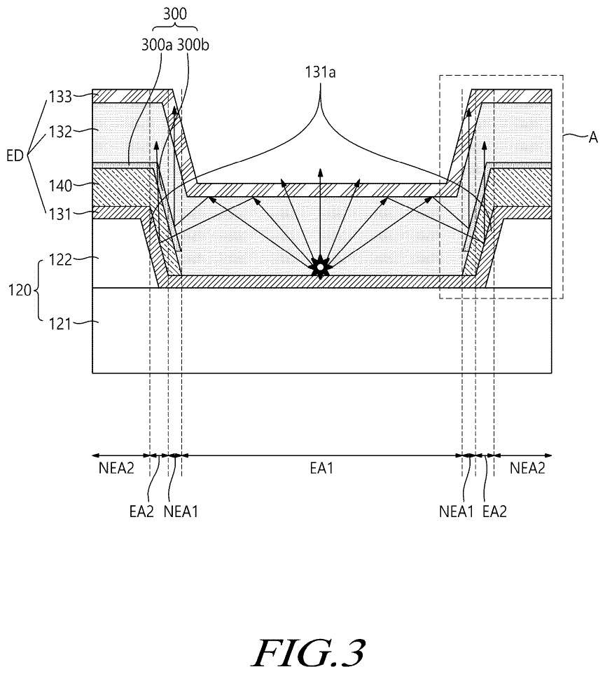

Hereinafter, a method for solving the above issues is described with reference to FIGS. 3 to 5.

FIG. 3 is a view illustrating an example of a cross-sectional structure of a display device according to embodiments of the disclosure.

Hereinafter, contents overlapping those described with reference to FIG. 2 are omitted.

Referring to FIG. 3, a getter layer 300 may be disposed in at least a partial area on the bank layer 140.

The getter layer 300 may be a metal layer or a metal oxide layer. The getter layer 300 may include a metal or metal oxide such as magnesium (Mg), barium (Ba), silver (Ag), zinc (Zn), calcium oxide (CaO), indium oxide (IGZO), or the like.

The getter layer 300 may reflect or partially transmit incident light. In other words, the material constituting the getter layer 300 may be a semi-permeable material. However, the disclosure is not limited thereto, and the material constituting the getter layer 300 may be a transmissive material that completely transmits light or an opaque material that completely reflects light.

The getter layer 300 may refer to a layer in which the metal or metal oxide is deposited in a thin film form. The getter layer 300 may be deposited using a sputtering method.

The thickness of the getter layer 300 may be about 2 nm to 3 nm, but is not necessarily limited thereto. Further, the thickness of the getter layer 300 may be smaller than the thickness of the light emitting layer 132. In other words, the getter layer 300 may be spaced apart from the cathode electrode 133.

The getter layer 300 may include a getter flat portion 300a disposed along a flat surface of the bank layer 140 and a getter inclined portion 300b disposed along an inclined surface of the bank layer 140.

The thicknesses of the getter flat portion 300a and the getter inclined portion 300b may be the same, or the thickness of the getter flat portion 300a may be larger than the thickness of the getter inclined portion 300b.

The getter inclined portion 300b may have the same angle as the anode electrode inclined portion 131a.

The getter inclined portion 300b may be disposed in the first non-emission area NEA1 and the second emission area EA2. However, the disclosure is not limited thereto, and the getter inclined portion 300b may be partially disposed in the second non-emission area NEA2.

The getter inclined portion 300b may be spaced apart from the anode electrode 131. In other words, the lowermost end of the getter inclined portion 300b may not contact the upper surface of the anode electrode 131. In other words, the distance from the lowermost end of the getter layer 300 to the first planarization layer 121 may be larger than the distance from the lowermost end of the bank layer 140 to the first planarization layer 121.

Since the getter inclined portion 300b is disposed to be spaced apart from the anode electrode 131, it is possible to prevent the getter layer 300 from affecting the light emitting element ED.

Further, as the getter inclined portion 300b is disposed to be spaced apart from the anode electrode 131, the getter inclined portion 300b may not be disposed in the first emission area EA1.

Depending on the distance between the getter inclined portion 300b and the anode electrode, the getter inclined portion 300b may be disposed in both the first non-emission area NEA1 and the second emission area EA2, or may be disposed only in the second emission area EA2.

When the getter inclined portion 300b is disposed only in the second emission area EA2 or when the getter inclined portion 300b is disposed in both the first non-emission area NEA1 and the second emission area EA2, the getter layer 300 may reflect at least a portion of incident light. For example, when the material constituting the getter layer 300 is a semi-permeable material, the getter layer 300 may reflect a portion of light incident from the light emitting layer 132 and transmit a portion of the light.

In particular, the getter inclined portion 300b may reflect light incident from the light emitting layer 132 in a direction perpendicular to the substrate (not shown) or the first planarization layer 121.

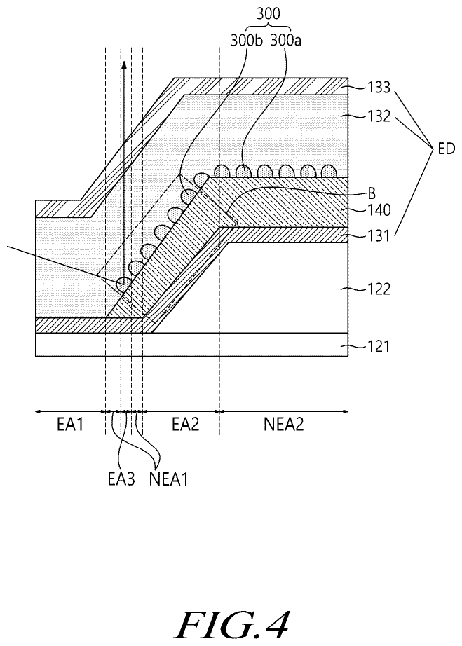

As the getter inclined portion 300b reflects light incident from the light emitting layer 132 in a vertical direction, a new emission area may be formed in an area in which the getter inclined portion 300b is disposed. The new emission area is described in detail with reference to FIG. 4.

FIG. 4 is an enlarged view of area A of FIG. 3.

Referring to FIG. 4, the getter layer 300 may be disposed so that a plurality of nanoparticles are spaced apart from each other.

The getter layer 300 may be formed of a plurality of nanoparticles during deposition. Alternatively, the plurality of nanoparticles may be formed when the getter layer 300 is deposited on the bank layer 140 by performing surface treatment to adjust the roughness of the upper surface of the bank layer 140. Here, the getter layer 300 may be formed of a plurality of nanoparticles because the materials forming the getter layer 300 aggregate with each other during the deposition process of the getter layer 300.

The thickness of the getter layer 300 formed of a plurality of nanoparticles may be less than 3 nm. In other words, since the thickness of the agglomerated getter layer 300 is smaller than the thickness of the light emitting layer 132, the getter layer 300 may be spaced apart from the cathode electrode 133.

The plurality of nanoparticles of the getter layer 300 may be spaced apart from each other. The separation distance between the plurality of nanoparticles may vary depending on the sputtering condition or the thickness of the getter layer 300 to be deposited. For example, the smaller the thickness of the deposited getter layer 300, the lower the density of the getter layer 300. Therefore, as the materials forming the getter layer 300 agglomerate, the separation distance between the plurality of nanoparticles may increase.

The getter layer 300, which is the plurality of nanoparticles, may have a getter flat portion 300a and a getter inclined portion 300b, which are a plurality of nanoparticles.

The getter inclined portion 300b may be disposed only in the second emission area EA2 as described above, but may be disposed up to the first non-emission area NEA1.

When the getter inclined portion 300b is disposed in the first non-emission area NEA1, at least one third emission area EA3 may be formed between the first non-emission areas NEA1.

In other words, since the light emitted from the light emitting layer 132 may be reflected from the getter inclined portion 300b and travel in a direction perpendicular to the substrate, a new emission area may be generated in each area in which the plurality of nanoparticles constituting the getter inclined portion 300b are disposed.

Hereinafter, a principle in which the getter layer 300 or the getter inclined portion 300b reflects incident light is described in detail.

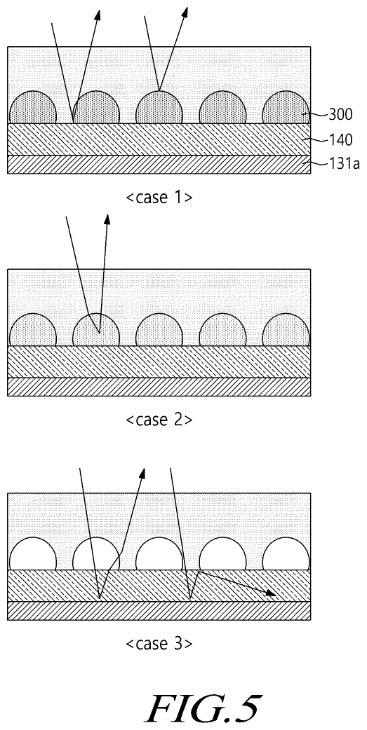

FIG. 5 is a view illustrating various examples of part B of FIG. 4.

Referring to FIG. 5, as described above, the getter layer 300 may be disposed on the bank layer 140 and may have the form of a plurality of nanoparticles. Further, the plurality of nanoparticles may be spaced apart from each other.

Immediately after the getter layer 300 is deposited, the plurality of nanoparticles of the getter layer 300 may be opaque particles such as <case 1>. In other words, the light incident on the getter layer 300 may not pass through the plurality of nanoparticles and may be mostly reflected from the surface of the getter layer 300.

As shown in <case 1>, the light incident on the getter layer 300 may be reflected from the upper surface or the side surface of the getter layer 300.

A portion of the light reflected from the upper surface or the side surface of the getter layer 300 may travel in a direction perpendicular to the substrate as illustrated in FIG. 4. Accordingly, the third emission area EA3 may be formed in the getter layer 300, i.e., an area in which a plurality of nanoparticles are disposed.

The plurality of nanoparticles of the getter layer 300 may change into semi-transmissive particles that partially transmit light as in <case 2> over time. Since the semi-transmissive particles partially transmit and partially reflect light, a portion of the light incident on the getter layer 300 may pass through the getter layer 300. In this case, since the getter layer 300 is not completely transparent, light passing through the getter layer 300 may be reflected again inside the getter layer 300.

As shown in <case 2>, the light incident on the getter layer 300 is not completely transmitted through the getter layer 300 and is reflected from the inside of the getter layer 300 and travels to the outside.

The light reflected from the inside of the getter layer 300 may travel in a direction perpendicular to the substrate as illustrated in FIG. 4. Accordingly, the third emission area EA3 may be formed in the getter layer 300, i.e., an area in which a plurality of nanoparticles are disposed.

<case 2> of FIG. 5 illustrates an example in which all the nanoparticles are semi-transmissive particles but, like <case 1>, some of the nanoparticles may be opaque particles and some may be semi-transmissive particles.

The plurality of nanoparticles of the getter layer 300 may be changed into transparent particles that completely transmit light as in <case 3> over time. In other words, all the light incident on the getter layer 300 may pass through the getter layer 300. Light passing through the getter layer 300 may be transmitted through the bank layer 140 and be reflected again from the anode electrode inclined portion 131a.

The light reflected from the anode electrode inclined portion 131a may pass through the bank layer 140 and then pass through the transparent getter layer 300 to travel in the vertical direction.

Here, if the getter layer 300 is absent, a portion of the light reflected from the anode electrode inclined portion 131a may pass through the bank layer 140 and then be totally reflected from the upper surface of the bank layer 140. In other words, a portion of the light reflected from the anode electrode inclined portion 131a is not emitted to the outside of the display device 100 but is trapped inside the display device 100.

However, when the getter layer 300 is present, due to the difference in refractive index between the bank layer 140 and the getter, the light reflected from the anode electrode inclined portion 131a may be emitted to the outside of the display device 100 without total reflection as illustrated in <case 3>.

In other words, the light reflected from the anode electrode inclined portion 131a may travel in a direction perpendicular to the substrate as illustrated in FIG. 4, and accordingly, the third emission area EA3 may be formed in the getter layer 300, i.e., the area in which the plurality of nanoparticles are disposed.

<case 3> of FIG. 5 illustrates an example in which all of the nanoparticles are transparent particles but, like <case 1>, some of the nanoparticles may be opaque particles and some may be transparent particles. Or, like <case 2>, some may be semi-transmissive particles, and some may be transparent particles. Alternatively, opaque particles, semi-transmissive particles, and transparent particles may all coexist.

As described with reference to <case 1>, <case 2>, and <case 3> of FIG. 5, when the getter layer 300 is disposed on the bank layer 140, in particular, when the getter inclined portion 300b is disposed along the anode electrode inclined portion 131a of the anode electrode 131, a new emission area, i.e., the third emission area EA3, may be additionally generated in the area where the getter layer 300 is disposed. Therefore, the light extraction efficiency of the display device 100 may be increased compared to the case where there is no getter layer 300.

Further, the getter layer 300 may absorb harmful gases generated inside and outside the display device 100, thereby preventing the performance of the display device 100 from deteriorating due to harmful gases generated inside and outside the display device 100, and delaying the occurrence time of a dark spot, thereby enhancing the reliability of the display device 100.

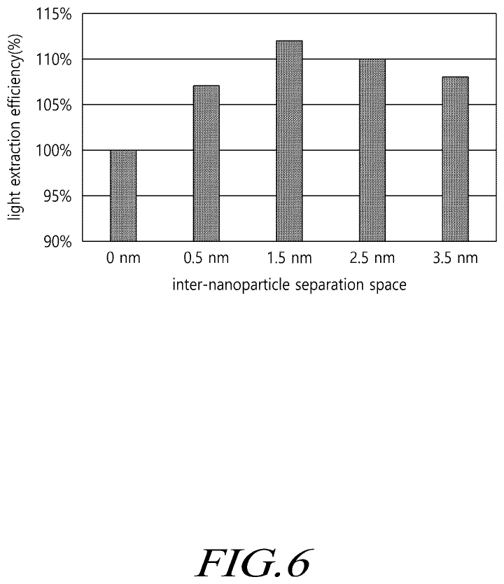

FIG. 6 is a graph illustrating changes in characteristics of a display device according to embodiments of the disclosure.

Referring to FIG. 6, it may be identified that the light extraction efficiency varies according to the separation distance of the plurality of nanoparticles of the getter layer 300.

As described above, the separation distance between the plurality of nanoparticles of the getter layer 300 may vary depending on the sputtering condition of the getter layer 300 and the thickness of the getter layer 300 to be deposited.

Referring to FIG. 6, it may be identified that the light extraction efficiency increases as the separation distance of the plurality of nanoparticles of the getter layer 300 decreases.

When the separation distance between the nanoparticles increases, the number of nanoparticles disposed in the same area decreases, and thus the amount of light reflected from the surface of the nanoparticles, light reflected from the inside of the nanoparticles, or light reflected from the anode electrode 131 and passing through the nanoparticles decreases, thereby reducing light extraction efficiency.

However, when the separation distance of the plurality of nanoparticles of the getter layer 300 decreases to a predetermined level or more, it may be identified that the light extraction efficiency is rather reduced.

When the getter layer 300 is opaque, if the separation distance is reduced to a predetermined level or more, the surface area of the entire getter layer 300 capable of reflecting light is reduced, and thus less light is reflected, thereby reducing light extraction efficiency.

Even when the getter layer 300 is semi-transmissive, if the separation distance is reduced to a predetermined level or more, the amount of light lost at the interface between the nanoparticles increases, and thus light extraction efficiency may be reduced.

Even when the getter layer 300 is transparent, if the separation distance is reduced to a predetermined level or more, the amount of light lost at the interface between the nanoparticles increases, and thus light extraction efficiency may be reduced.

In order to prevent the light extraction efficiency from being excessively reduced, it is preferable that the separation distance between the plurality of nanoparticles of the getter layer 300 is 0.5 nm or more.

When the plurality of nanoparticles of the getter layer 300 form a separation distance of a predetermined level or more as described above, the light extraction efficiency of the display device 100 increases.

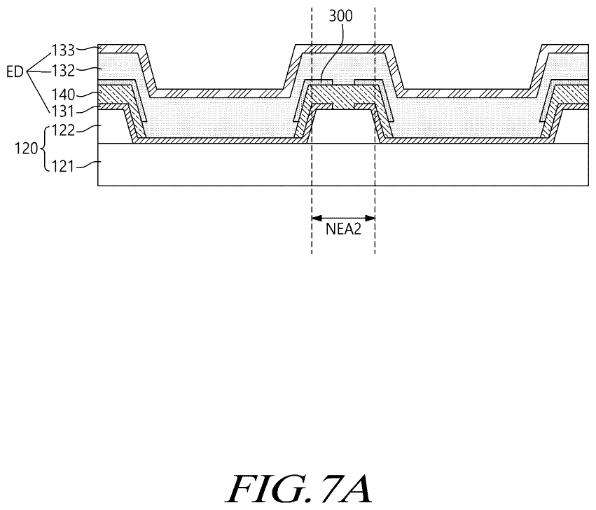

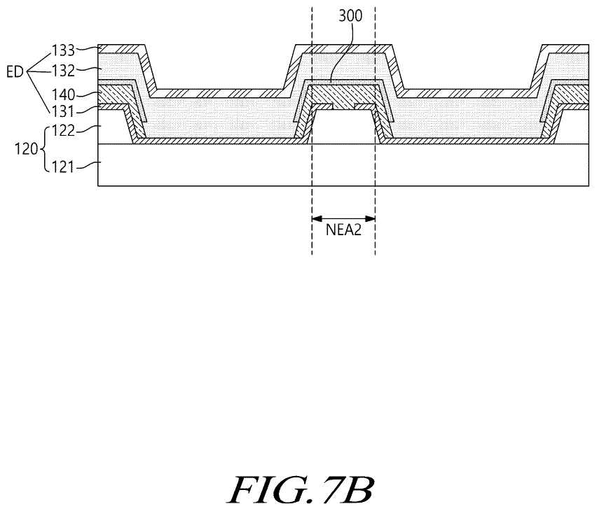

FIGS. 7A and 7B are views illustrating another example of a cross-sectional structure of a display device according to embodiments of the disclosure.

Hereinafter, contents overlapping those described with reference to FIGS. 3 to 6 are omitted.

Referring to FIGS. 7A and 7B, the second non-emission area NEA2 may be an area between the respective emission areas of adjacent subpixels SP (not shown).

As described above, the getter flat portion 300a of the getter layer 300 may be disposed in the second non-emission area NEA2.

The getter flat portion 300a may have a structure separated from the second non-emission area NEA2 as illustrated in FIG. 7A.

Alternatively, the getter flat portion 300b may have a structure connected in the second non-emission area NEA2 as illustrated in FIG. 7B. In other words, the getter flat portion 300b may be disposed to cover the entire bank layer 140 in the second non-emission area NEA2.

As described above, the getter layer 300 may be spaced apart from the respective anode electrodes 131 of the plurality of subpixels.

In other words, as illustrated in FIGS. 7A and 7B, the getter layer 300 may have a structure floated in the second non-emission area NEA2.

Since the getter layer 300 has a floating structure, even if the getter layer 300 is disposed between emission areas of adjacent subpixels, the respective anode electrodes 131 of the adjacent subpixels are not electrically connected to each other. Therefore, interference between adjacent subpixels may be prevented.

Further, as illustrated in FIG. 7B, when the getter layer 300 has a structure of being connected in the second non-emission area NEA2, it is possible to absorb more harmful gases generated inside and outside the display device 100, and thus it is possible to further mitigate the reliability degradation of the display device 100 due to performance degradation.

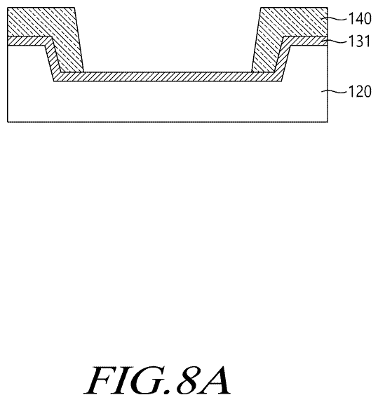

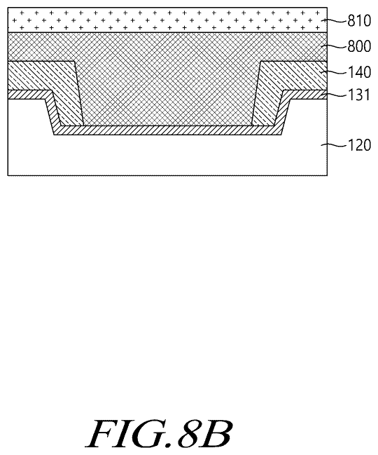

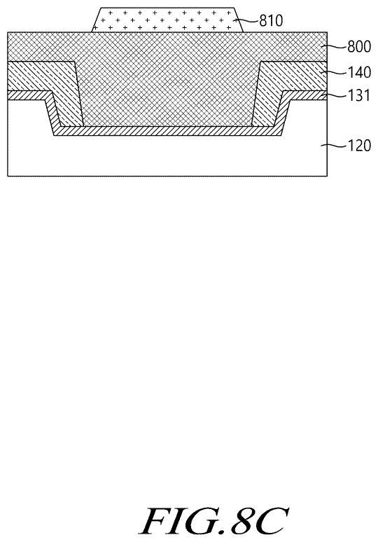

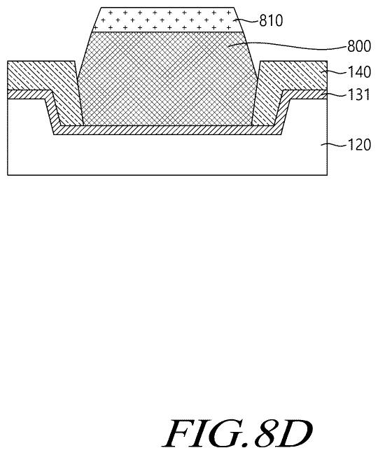

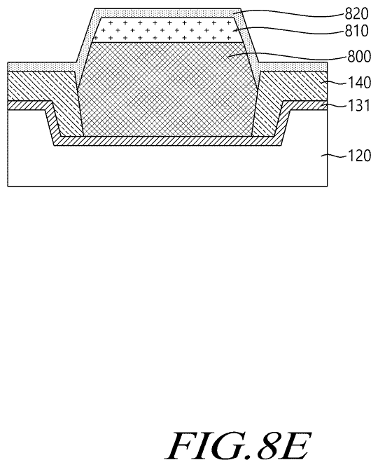

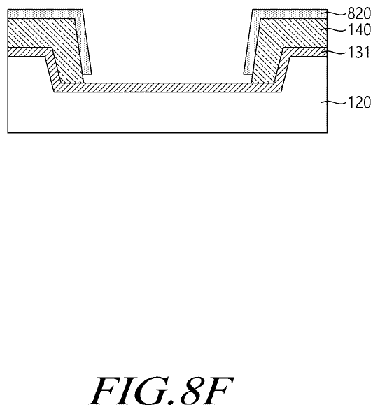

FIGS. 8A, 8B, 8C, 8D, 8E, and 8F are views illustrating an example of a method for manufacturing a display device according to embodiments of the disclosure.

Referring to FIG. 8A, the anode electrode 131 is disposed on the planarization layer 120 and, after the anode electrode 131 is disposed, the bank layer 140 may be disposed to have an opening. As described above, the first emission area may be defined by the opening of the bank layer 140.

Referring to FIG. 8B, a protective layer (or shield layer) 800 may be formed on the anode electrode 131 and the bank layer 140. The protective layer 800 may be a water-based protective layer or a fluorine-based protective layer. When a pattern is formed using the protective layer 800, a relatively fine pattern may advantageously be implemented.

The protective layer 800 may be later removed by a solvent.

A photoresist 810 may be disposed on the protective layer 800. The photoresist 810 is a material used for pattern formation and may be later removed by a solvent.

Referring to FIG. 8C, a portion of the photoresist 810 may be removed using a developer.

Referring to FIG. 8D, after removing the photoresist 810, a portion of the protective layer 800 may be removed using a solvent capable of removing the protective layer 800. After a portion of the protective layer 800 is removed, a groove may be formed between the protective layer 800 and the bank layer 140 as illustrated in FIG. 8D.

Referring to FIG. 8E, a metal or metal oxide layer 820 may be formed on the bank layer 140, the protective layer 800, and the photoresist 810. In this case, the metal or metal oxide layer 820 may fill the groove between the protective layer 800 and the bank layer 140.

Referring to FIG. 8F, after the metal or metal oxide layer 820 is formed, all of the protective layer 800 and the photoresist 810 may be removed. In the process of removing all of the protective layer 800 and the photoresist 810, the metal or metal oxide layer 820 covering the upper surface and the side surface of the photoresist 810 may be removed together, and a portion of the metal or metal oxide layer 820 covering the side surface of the protective layer 800 may be removed together.

Referring to FIG. 8F, since the portion of the metal or metal oxide layer 820 that fills the groove between the protective layer 800 and the bank layer 140 is not removed, the metal or metal oxide layer 820 may be formed to have a separation distance from the anode electrode 131. In this case, as the groove between the protective layer 800 and the bank layer 140 illustrated in FIG. 8D is formed deeper, the metal or metal oxide layer 820 is deposited to a lower position, and thus the separation distance between the anode electrode 131 and the lowermost end of the metal or metal oxide layer 820 illustrated in FIG. 8F may be reduced.

As the metal or metal oxide layer 820 is spaced apart from the anode electrode 131, electrical connection between adjacent subpixels may be prevented.

Further, as the metal or metal oxide layer 820 absorbs harmful gases generated inside and outside the display device 100, it is possible to prevent the performance of the display device 100 from deteriorating and to delay the occurrence of a dark spot, thereby enhancing the reliability of the display device 100.

Moreover, as the metal or metal oxide layer 820 is disposed, more light reflected from the light emitting layer may be emitted to the outside, thereby increasing light extraction efficiency.

Embodiments of the disclosure described above are briefly described below.

According to embodiments of the disclosure, a display device may comprise an anode electrode disposed on a substrate and having a concave portion, a bank layer disposed on a portion on the anode electrode, a getter layer disposed in at least a partial area of the bank layer, a light emitting layer disposed on the getter layer and the anode electrode, and a cathode electrode disposed on the light emitting layer.

In the display device according to embodiments of the disclosure, the anode electrode may have an anode electrode inclined portion in an area overlapping the bank layer.

In the display device according to embodiments of the disclosure, the getter layer may be a layer including a plurality of nanoparticles. The plurality of nanoparticles may be disposed to be spaced apart from each other on the bank layer.

In the display device according to embodiments of the disclosure, a separation distance between the plurality of nanoparticles may be larger than 0.5 nm.

In the display device according to embodiments of the disclosure, the getter layer may be spaced apart from the anode electrode.

In the display device according to embodiments of the disclosure, a thickness of the getter layer may be smaller than a thickness of the light emitting layer.

In the display device according to embodiments of the disclosure, the substrate may include an emission area and a non-emission area. The getter layer may be disposed to cover a whole of the bank layer in the non-emission area.

In the display device according to embodiments of the disclosure, at least some of the plurality of nanoparticles may be semi-transmissive particles.

In the display device according to embodiments of the disclosure, the getter layer may include a metal or metal oxide.

According to embodiments of the disclosure, a display device may comprise a first planarization layer on a substrate, a second planarization layer disposed on the first planarization layer and including an opening, a bank layer disposed on the second planarization layer, and a getter layer disposed in at least a partial area on the bank layer.

In the display device according to embodiments of the disclosure, the getter layer may be a layer including a plurality of nanoparticles. The plurality of nanoparticles may be disposed to be spaced apart from each other on the bank layer.

In the display device according to embodiments of the disclosure, a separation distance between the plurality of nanoparticles may be larger than 0.5 nm.

In the display device according to embodiments of the disclosure, a distance between a lowermost end of the getter layer and the first planarization layer may be larger than a distance between a lowermost end of the bank layer and the first planarization layer.

In the display device according to embodiments of the disclosure, the substrate may include an emission area and a non-emission area. The getter layer may be disposed to cover a whole of the bank layer in the non-emission area.

In the display device according to embodiments of the disclosure, at least some of the plurality of nanoparticles may be semi-transmissive particles.

In the display device according to embodiments of the disclosure, the getter layer may include a metal or metal oxide.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed:

1. A display device, comprising:
an anode electrode disposed on a substrate;
a bank layer disposed on a portion of the anode electrode;
a getter layer disposed in at least a partial area on the bank layer;
a light emitting layer disposed on the getter layer and the anode electrode; and
a cathode electrode disposed on the light emitting layer.

2. The display device of claim 1, wherein the anode electrode has an anode electrode inclined portion in an area overlapping the bank layer.

3. The display device of claim 1, wherein the getter layer is a layer including a plurality of nanoparticles, and wherein the plurality of nanoparticles are disposed to be spaced apart from each other on the bank layer.

4. The display device of claim 3, wherein a separation distance between the plurality of nanoparticles is larger than 0.5 nm.

5. The display device of claim 1, wherein the getter layer is spaced apart from the anode electrode.

6. The display device of claim 1, wherein a thickness of the getter layer is smaller than a thickness of the light emitting layer.

7. The display device of claim 1, wherein the substrate includes an emission area and a non-emission area, and
wherein the getter layer is disposed to cover a whole of the bank layer in the non-emission area.

8. The display device of claim 3, wherein at least some of the plurality of nanoparticles are semi-transmissive particles.

9. The display device of claim 1, wherein the getter layer includes a metal or metal oxide.

10. A display device, comprising:
a first planarization layer on a substrate;
a second planarization layer disposed on the first planarization layer and including an opening;
a bank layer disposed on the second planarization layer; and
a getter layer disposed in at least a partial area on the bank layer.

11. The display device of claim 10, wherein the getter layer is a layer including a plurality of nanoparticles, and wherein the plurality of nanoparticles are disposed to be spaced apart from each other on the bank layer.

12. The display device of claim 11, wherein a separation distance between the plurality of nanoparticles is larger than 0.5 nm.

13. The display device of claim 10, wherein a distance between a lowermost end of the getter layer and the first planarization layer is larger than a distance between a lowermost end of the bank layer and the first planarization layer.

14. The display device of claim 10, wherein the substrate includes an emission area and a non-emission area, and
wherein the getter layer is disposed to cover a whole of the bank layer in the non-emission area.

15. The display device of claim 11, wherein at least some of the plurality of nanoparticles are semi-transmissive particles.

16. The display device of claim 10, wherein the getter layer includes a metal or metal oxide.
